(19) United States
(12) Patent Application Publication
(10) Pub. No.: US 2022/0093368 A1
(43) Pub. Date: Mar. 24, 2022

(54) WAFER NON-UNIFORMITY TWEAKING THROUGH LOCALIZED ION ENHANCED PLASMA (IEP)

(71) Applicant: Applied Materials, Inc., Santa Clara, CA (US)

(72) Inventors: Saketh Pemmasani, Hyderabad (IN); Akshay Dhanakshirur, Hubli (IN); Mayur Govind Kulkarni, Bangalore (IN); Khokan Chandra Paul, Cupertino, CA (US); Madhu Santosh Kumar Mutyala, Santa Clara, CA (US)

(73) Assignee: Applied Materials, Inc., Santa Clara, CA (US)

(21) Appl. No.: 17/026,840

(22) Filed: Sep. 21, 2020

(51) Int. Cl. H01J 37/32; C23C 16/455

(52) U.S. Cl. CPC H01J 37/32642; C23C 16/45591

(57) ABSTRACT

semiconductor processing chambers include a gasbox. The chambers may include a substrate support. The chambers may include a blocker plate positioned between the gasbox and the substrate support. The blocker plate may define a plurality of apertures. The chambers may include a faceplate positioned between the blocker plate and the substrate support. The faceplate may be characterized by a first surface facing the blocker plate and a second surface opposite the first surface. The second surface and the substrate support may at least partially define a processing region within the chamber. The faceplate may define an inner plurality of apertures. Each of the inner apertures may include a generally cylindrical aperture profile. The faceplate may define an outer plurality of apertures that are positioned radially outward from the inner apertures. Each of the outer apertures may include a conical aperture profile that extends through the second surface.

### TECHNICAL FIELD

The present technology relates to components and apparatuses for semiconductor manufacturing. More specifically, the present technology relates to processing chamber distribution components and other semiconductor processing equipment.

### BACKGROUND OF THE INVENTION

Integrated circuits are made possible by processes which produce intricately patterned material layers on substrate surfaces. Producing patterned material on a substrate requires controlled methods for forming and removing material. Chamber components often deliver processing gases to a substrate for depositing films or removing materials. To promote symmetry and uniformity, many chamber components may include regular patterns of features, such as apertures, for providing materials in a way that may increase uniformity. However, this may limit the ability to tune recipes for on-wafer adjustments.

Thus, there is a need for improved systems and methods that can be used to produce high quality devices and structures. These and other needs are addressed by the present technology.

### BRIEF SUMMARY OF THE INVENTION

Exemplary semiconductor processing chambers may include a gasbox. The chambers may include a substrate support. The chambers may include a blocker plate positioned between the gasbox and the substrate support. The blocker plate may define a plurality of apertures through the plate. The chambers may include a faceplate positioned between the blocker plate and substrate support. The faceplate may be characterized by a first surface facing the blocker plate and a second surface opposite the first surface. The second surface of the faceplate and the substrate support may at least partially define a processing region within the semiconductor processing chamber. The faceplate may define an inner plurality of apertures through the faceplate. Each of the inner plurality of apertures may have a generally cylindrical aperture profile. The faceplate may define an outer plurality of apertures through the faceplate that are positioned radially outward of the inner plurality of apertures. Each of the outer plurality of apertures may have a conical aperture profile that extends through the second surface of the faceplate.

In some embodiments, each of the outer plurality of apertures may have a diameter at the second surface of the faceplate that is larger than a corresponding diameter of each of the inner plurality of apertures. A conductance of the faceplate may be substantially constant across all regions of the faceplate. Each of the outer plurality of apertures may include an upper aperture profile that extends through the first surface of the faceplate. The upper aperture profile may be characterized by a substantially cylindrical profile. Each of the outer plurality of apertures may further include a choke that extends between the upper aperture profile and the conical aperture profile. The choke may have a smaller diameter than each of the upper aperture profile and the conical aperture profile. A portion of each of the inner plurality of apertures and a portion of each of the outer plurality of apertures may be characterized by a same diameter. The portion of each of the inner plurality of apertures may extend through the second surface of the faceplate. The portion of each of the outer plurality of apertures may be disposed at a medial portion of a thickness of the faceplate and may be disposed above the conical aperture profile. The outer plurality of apertures may be arranged about the faceplate in a number of circumferentially arranged rows.

Some embodiments of the present technology may encompass semiconductor processing chamber faceplates. The faceplates may include a first surface and a second surface opposite the first surface. The faceplates may define an inner plurality of apertures through the faceplate. Each of the inner plurality of apertures may include an aperture profile having a generally cylindrical section that extends through the second surface of the faceplate. The faceplates may define an outer plurality of apertures through the faceplate that are positioned radially outward from the inner plurality of apertures. Each of the outer plurality of apertures may include a conical aperture profile that extends through the second surface of the faceplate.

In some embodiments, the inner plurality of apertures may be disposed in a central region of the faceplate. The outer plurality of apertures may be disposed in an annular region of the faceplate that is radially outward from the central region of the faceplate. An inner edge of the annular region may be positioned at least 135 mm from a center of the faceplate. The conical profile of each of the outer plurality of apertures may transition to a choke at a medial position of the faceplate between the first surface of the faceplate and the second surface of the faceplate. The aperture profile of each of the outer plurality of apertures may transition from the choke to a substantially cylindrical profile extending to the first surface of the faceplate. The generally cylindrical section of the aperture profile of each of the inner plurality of apertures and the choke of each of the outer plurality of apertures may have a substantially similar diameter. The generally cylindrical section of the aperture profile of each of the inner plurality of apertures may have a length that is greater than a length of the choke of each of the outer plurality of apertures. The aperture profile of each of the inner plurality of apertures may include an additional cylindrical section that extends through the first surface of the faceplate. The additional cylindrical section may have a greater diameter than the generally cylindrical section. An aperture density of the inner plurality of apertures may be greater than an aperture density of the outer plurality of apertures. The aperture density of the inner plurality of apertures may be at least twice as great as the aperture density of the outer plurality of apertures.

Some embodiments of the present technology may encompass methods of semiconductor processing. The methods may include flowing a precursor into a processing chamber. The processing chamber may include a faceplate and a substrate support on which a substrate is disposed. A processing region of the processing chamber may be at least partially defined between the faceplate and the substrate support. The faceplate may define an inner plurality of apertures through which the precursor flows. Each of the inner plurality of apertures may have a generally cylindrical aperture profile. The faceplate may define an outer plurality of apertures through which the precursor flows that are positioned radially outward of the inner plurality of apertures. Each of the outer plurality of apertures may have a conical aperture profile that extends through a surface of the faceplate facing the substrate support. The methods may include generating a plasma of the precursor within the processing region of the processing chamber. The methods may include depositing a material on the substrate. In some embodiments, the material deposited may be characterized by a thickness proximate an edge of the substrate that is within 500 Å of a thickness at a center of the substrate.

Such technology may provide numerous benefits over conventional systems and techniques. For example, embodiments of the present technology may allow controlled deposition at an edge region of a substrate. Additionally, the components may maintain edge region plasma generation to reduce effects on plasma density and distribution. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows a schematic partial cross-sectional view of an exemplary faceplate according to some embodiments of the present technology.

FIG. 4A shows a schematic bottom plan view of an exemplary faceplate according to some embodiments of the present technology.

FIG. 4B shows a schematic bottom plan view of an exemplary faceplate according to some embodiments of the present technology.

FIG. 5 shows operations of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. The precursors may be distributed through one or more components within the chamber, which may produce a radial or lateral distribution of delivery to provide increased formation or removal at the substrate surface.

As device features reduce in size, tolerances across a substrate surface may be reduced, and material property differences across a film may affect device realization and uniformity. Many chambers include a characteristic process signature, which may produce non-uniformity across a substrate. Temperature differences, flow pattern uniformity, and other aspects of processing may impact the films on the substrate, creating film uniformity differences across the substrate for materials produced or removed. For example, one or more devices may be included within a processing chamber for delivering and distributing precursors within a processing chamber. A blocker plate may be included in a chamber to provide a choke in precursor flow, which may increase residence time at the blocker plate and lateral or radial distribution of precursors. A faceplate may further improve uniformity of delivery into a processing region, which may improve deposition or etching.

In some non-limiting examples of deposition processes, precursor flow rate may impact operation based on the film being formed. For example, while some processes may actually lower deposition rates by increasing some precursor flows, other processes may have a proportional increase in deposition rate with increased precursor flow rates across a wide range. Consequently, to increase throughput, some deposition processes may be characterized by precursor delivery rates of greater than or about 5 L/min, greater than or about 7 L/min, greater than or about 10 L/min, or greater. To accommodate these increased rates, some blocker plate designs may be characterized by increased conductance, such as by increasing the number or size of apertures, which may facilitate cleaning operations and allow increased precursor delivery rates. However, this may affect the blocking function of the plate, and precursor delivery may be increased, such as with an increased central delivery, depending on the chamber inlet. This flow profile may continue through the faceplate and into the processing region, which may result in non-uniformity of deposition on the substrate. In particular, a central region of the substrate may develop a thicker deposition profile than an edge region of the substrate.

The present technology overcomes these challenges during these higher delivery rate processes, as well as for any other process that may produce a center peak formation. By utilizing one or more chamber components that may increase a plasma ion density over edge regions of the substrate, increased control of the film formation may be afforded. Accordingly, the present technology may produce improved film deposition characterized by improved uniformity across a surface of the substrate.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

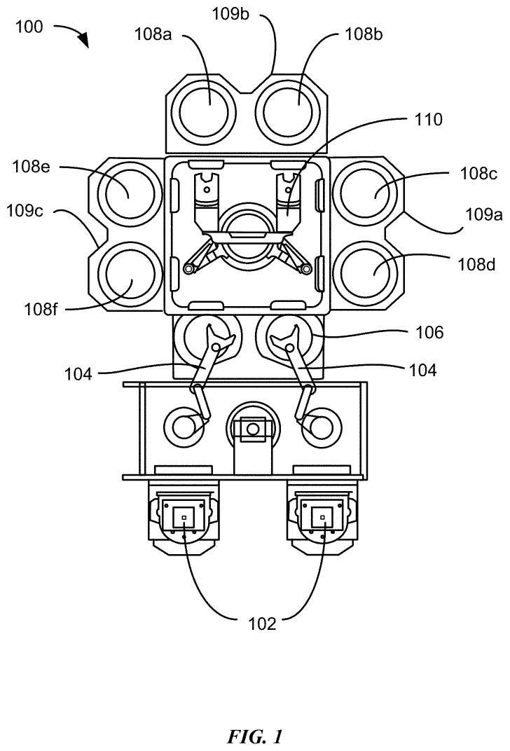

FIG. 1 shows a top plan view of one embodiment of a processing system 100 of deposition, etching, baking, and curing chambers according to embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

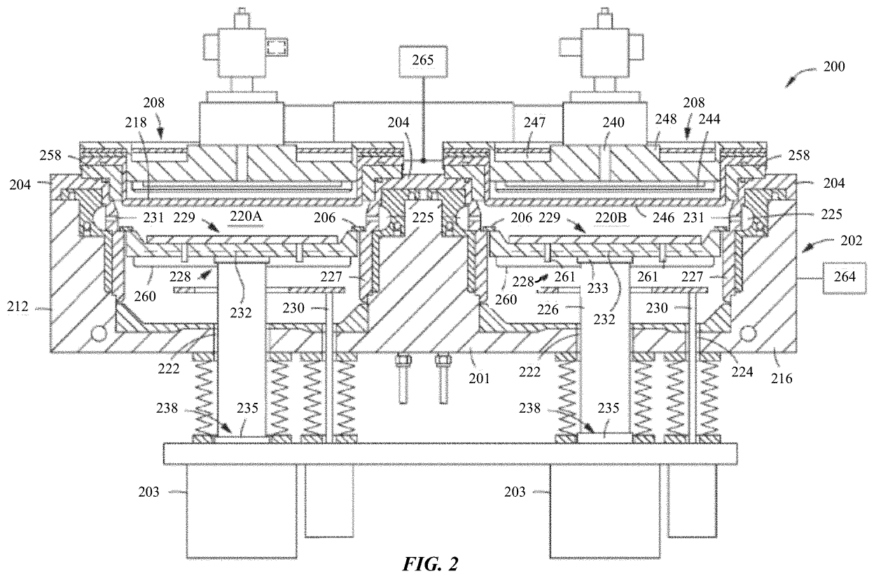

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include faceplates or other components or assemblies according to embodiments of the present technology as further described below. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a gas delivery assembly 218 into the processing region 220B. The gas delivery assembly 218 may include a gasbox 248 having a blocker plate 244 disposed intermediate to a faceplate 246. A radio frequency (“RF”) source 265 may be coupled with the gas delivery assembly 218, which may power the gas delivery assembly 218 to facilitate generating a plasma region between the faceplate 246 of the gas delivery assembly 218 and the pedestal 228, which may be the processing region of the chamber. In some embodiments, the RF source may be coupled with other portions of the chamber body 202, such as the pedestal 228, to facilitate plasma generation. A dielectric isolator 258 may be disposed between the lid 204 and the gas delivery assembly 218 to prevent conducting RF power to the lid 204. A shadow ring 206 may be disposed on the periphery of the pedestal 228 that engages the pedestal 228.

An optional cooling channel 247 may be formed in the gasbox 248 of the gas distribution system 208 to cool the gasbox 248 during operation. A heat transfer fluid, such as water, ethylene glycol, a gas, or the like, may be circulated through the cooling channel 247 such that the gasbox 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

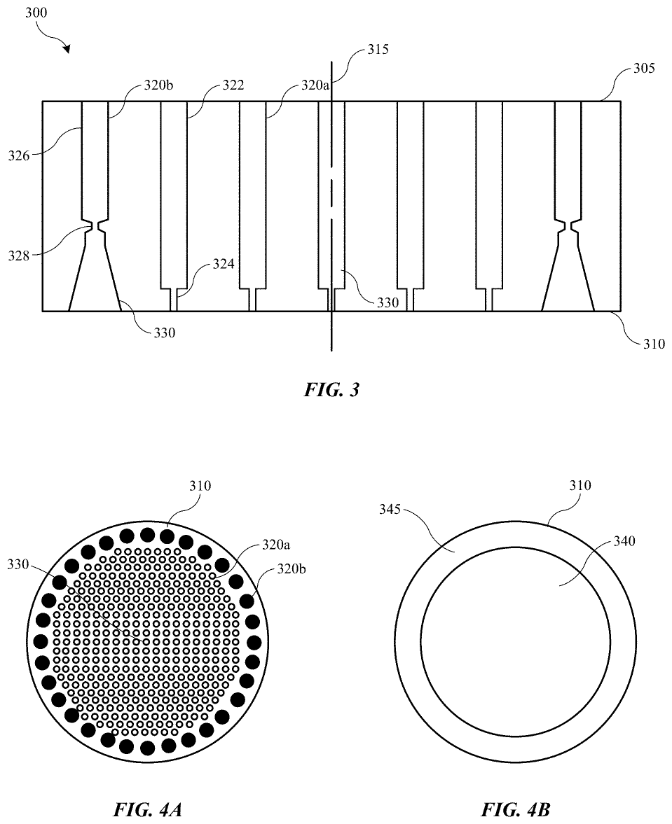

FIG. 3 shows a schematic partial cross-sectional view of an exemplary faceplate 300 according to some embodiments of the present technology. FIG. 3 may illustrate further details relating to components in system 200, such as for faceplate 246. Faceplate 300 is understood to include any feature or aspect of system 200 discussed previously in some embodiments. The faceplate 300 may be used to perform semiconductor processing operations including deposition of hardmask materials as previously described, as well as other deposition, removal, and cleaning operations. Faceplate 300 may show a partial view of a faceplate that may be incorporated in a semiconductor processing system, and may illustrate a view across a center of the faceplate, which may otherwise be of any size, and include any number of apertures. Although shown with a number of apertures extending outward laterally or radially, it is to be understood that the figure is included only for illustration of embodiments, and is not considered to be of scale. For example, exemplary faceplates may be characterized by a number of apertures along a central diameter of greater than or about 20 apertures as will be described further below, and may be characterized by greater than or about 25 apertures, greater than or about 30 apertures, greater than or about 35 apertures, greater than or about 40 apertures, greater than or about 45 apertures, greater than or about 50 apertures, or more.

As noted, faceplate 300 may be included in any number of processing chambers, including system 200 described above. Faceplate 300 may be included as part of the gas inlet assembly, such as with a gasbox and blocker plate. For example, a gasbox may define or provide access into a processing chamber. A substrate support may be included within the chamber, and may be configured to support a substrate for processing. A blocker plate may be included in the chamber between the gasbox and the substrate support. The blocker plate may include or define a number of apertures through the plate. The components may include any of the features described previously for similar components, as well as a variety of other modifications similarly encompassed by the present technology.

Faceplate 300 may be positioned within the chamber between the blocker plate and the substrate support as illustrated previously. Faceplate 300 may be characterized by a first surface 305 and a second surface 310, which may be opposite the first surface. In some embodiments, first surface 305 may be facing towards a blocker plate, gasbox, or gas inlet into the processing chamber. Second surface 310 may be positioned to face a substrate support or substrate within a processing region of a processing chamber. For example, in some embodiments, the second surface 310 of the faceplate and the substrate support may at least partially define a processing region within the chamber. Faceplate 300 may be characterized by a central axis 315, which may extend vertically through a midpoint of the faceplate, and may be coaxial with a central axis through the processing chamber.

Faceplate 300 may define a plurality of apertures 320 defined through the faceplate and extending from the first surface through the second surface. Each aperture 320 may provide a fluid path through the faceplate, and the apertures may provide fluid access to the processing region of the chamber. Depending on the size of the faceplate, and the size of the apertures, faceplate 300 may define any number of apertures through the plate, such as greater than or about 1,000 apertures, greater than or about 2,000 apertures, greater than or about 3,000 apertures, greater than or about 4,000 apertures, greater than or about 5,000 apertures, greater than or about 6,000 apertures, or more. As noted above, the apertures may be included in a set of rings extending outward from the central axis, and may include any number of rings as described previously. The rings may be characterized by any number of shapes including circular or elliptical, as well as any other geometric pattern, such as rectangular, hexagonal, or any other geometric pattern that may include apertures distributed in a radially outward number of rings. The apertures may have a uniform or staggered spacing, and may be spaced apart at less than or about 10 mm from center to center. The apertures may also be spaced apart at less than or about 9 mm, less than or about 8 mm, less than or about 7 mm, less than or about 6 mm, less than or about 5 mm, less than or about 4 mm, less than or about 3 mm, or less.

The rings may be characterized by any geometric shape as noted above, and in some embodiments, apertures may be characterized by a scaling function of apertures per ring. For example, in some embodiments a first aperture may extend through a center of the faceplate, such as along the central axis as illustrated. A first ring of apertures may extend about the central aperture, and may include any number of apertures, such as between about 4 and about 10 apertures, which may be spaced equally about a geometric shape extending through a center of each aperture. Any number of additional rings of apertures may extend radially outward from the first ring, and may include a number of apertures that may be a function of the number of apertures in the first ring. For example, the number of apertures in each successive ring may be characterized by a number of apertures within each corresponding ring according to the equation XR, where X is a base number of apertures, and R is the corresponding ring number. The base number of apertures may be the number of apertures within the first ring, and in some embodiments may be some other number, as will be described further below where the first ring has an augmented number of apertures. For example, for an exemplary faceplate having 5 apertures distributed about the first ring, and where 5 may be the base number of apertures, the second ring may be characterized by 10 apertures, (5)×(2), the third ring may be characterized by 15 apertures, (5)×(3), and the twentieth ring may be characterized by 100 apertures, (5)×(20). This may continue for any number of rings of apertures as noted previously, such as up to, greater than, or about 50 rings. In some embodiments each aperture of the plurality of apertures across the faceplate may be characterized by an aperture profile, which may be the same or different in embodiments of the present technology.

The apertures 320 may include any profile or number of sections having different profiles, such as illustrated. In some embodiments, the faceplates may have at least two sections, at least 3 sections, at least 4 sections, at least 5 sections, or more, defining different profiles through the aperture. In one non-limiting example as illustrated, the faceplate 300 includes two sections: an inner section with inner apertures 320a and an outer section with outer apertures 320b. Each inner aperture 320a may include an aperture profile including at least two sections. For example, first section 322 may extend from the first surface 305 of the faceplate 300, and may extend partially through the faceplate 300. In some embodiments, the first section 322 may extend at least about or greater than halfway, or at least about or greater than 75% of the way through a thickness of the faceplate between first surface 305 and second surface 310. First section 322 may be characterized by a substantially cylindrical profile as illustrated. By substantially is meant that the profile may be characterized by a cylindrical profile, but may account for machining tolerances and parts variations, as well as a certain margin of error. A second section 324 may extend from the second surface 310 of the faceplate 300, and may extend partially through the faceplate 300 and fluidly couple with the bottom end of the first section 322. Second section 324 may be characterized by a substantially cylindrical profile as illustrated. A diameter of the second section 324 may be less than a diameter of the first section 322. For example, the diameter of the first section 322 may be more than 1.5×, more than 1.75×, more than 2.0×, more than 2.25×, more than 2.5×, or greater than the diameter of the second section 324.

Additionally, radially outward of and extending about the plurality of inner apertures 320a, may be a plurality of outer apertures 320b. Each outer aperture 320b may include an aperture profile including at least three sections. For example, first section 326 may extend from the first surface 305 of the faceplate 300, and may extend partially through the faceplate 300. The first section 326 may be similar to the first section 322 of the inner apertures 320a. In some embodiments, the first section 326 may have a same or similar diameter as the first section 322 of the inner apertures 320a. In some embodiments, the first section 326 may extend at least about or greater than halfway through a thickness of the faceplate 300 between first surface 305 and second surface 310. First section 326 may be characterized by a substantially cylindrical profile as illustrated.

The first section 326 may transition to an optional second section 328, which may operate as a choke in the faceplate 300, and may increase distribution or uniformity of flow. As illustrated, the second section 328 may include a taper from first section 322 to a narrower diameter. A diameter of the second section 328 may be less than a diameter of the first section 326. For example, the diameter of the first section 326 may be more than 1.5×, more than 1.75×, more than 2.0×, more than 2.25×, more than 2.5×, or greater than the diameter of the second section 328. In some embodiments, the diameter of the choke of the second section 328 may be the same or similar to the diameter of the second section 324 of one of the inner apertures 320a. However, a length of the second section 328 of each outer aperture 320b may be shorter than the second section 234 of each of the inner apertures 320a. For example, the second section 328 of each outer aperture 320b may be about or less than half as long as the second section 324 of each of the inner apertures 320a.

The second section 328 may then flare to a third section 330. Third section 330 may extend from a position partially through the faceplate to the second surface 310. Third section 330 may extend less than halfway through the thickness of the faceplate 300, for example, or may extend up to or about halfway through the faceplate 300. Third section 330 may be characterized by a tapered profile from the second surface 310 in some embodiments, and may extend to include a cylindrical portion intersecting a flare from second section 328, when included. Third section 330 may be characterized by a conical profile in some embodiments, or may be characterized by a countersunk profile, among other tapered profiles. A diameter of the third section 330 at the second surface 310 may be greater than a diameter of both the first section 326 and the second section 328. For example, the diameter of the third section 330 may be more than 1.5×, more than 1.75×, more than 2.0×, more than 2.25×, more than 2.5×, or greater than the diameter of the first section 326. The diameter of the third section 330 may be more than 3.5×, more than 4.0×, more than 4.5×, more than 5.0×, more than 5.25×, or greater than the diameter of the second section 328.

The conical third section 330 of the outer apertures 320b helps increase the ion flux due to a pronounced hollow cathode effect in conical sections. This increased ion flux translates directly into a deposition rate improvement at edges of a substrate positioned beneath the faceplate 300. The increased deposition at the edges of the substrate may result in an overall increase in uniformity of deposition and a flatter thickness profile across the substrate.

FIG. 4A shows a schematic bottom plan view of an exemplary faceplate according to some embodiments of the present technology, and may illustrate a schematic view of faceplate 300, for example, such as along second surface 310. As illustrated, faceplate 300 may include a plurality of apertures 320, which may be distributed in an array along the faceplate 300. In some embodiments, the apertures 320 may be arranged as sets of rings extending radially outward along the faceplate 300. For example, from a central aperture 330, a first ring of apertures including a number of apertures, such as 8 apertures, extends about the central aperture. The next ring out, such as a second ring, may include 16 (or some other number) apertures extending about the first ring. This may follow the pattern as previously described for any number of rings as previously noted. The rings may be characterized by any number of shapes including circular or elliptical, as well as any other geometric pattern, such as rectangular, hexagonal, or any other geometric pattern that may include apertures distributed in a radially outward number of rings. It is to be understood that the figure is simply for illustrative purposes, and encompassed faceplates may be characterized by hundreds or thousands of apertures as noted previously, and which may be configured with any base number of apertures, for example. Along second surface 310, inner apertures 320a may show second section 324 and outer apertures 320b may show third section 330, for example. The apertures may all illustrate a channel extending through the faceplate. Although only a single set of outer apertures 320b is illustrated, outer apertures 320b may include a similar pattern as the rings of inner apertures 320a extending outward. For example, outer apertures 320b may be located as rings of apertures located beyond an outer radius of a substrate that may be positioned within a processing chamber.

For example, substrates may be characterized by any dimensions, such as rectangular or elliptical. For a circular substrate characterized by a 300 mm diameter, the radius of the substrate may be 150 mm. On the faceplate, apertures 320 that would be included beyond 135 mm, 136 mm, 137 mm, 138 mm, 139 mm, 140 mm, etc. from the central axis may be outer apertures 320b having conical third sections 330 that extend through the second surface 310 in some embodiments of the present technology. It is to be understood that similar modifications may be made for substrates of any other dimensions, such as 150 mm, 200 mm, 450 mm, 600 mm, or other dimensions of substrates as well. In some embodiments the outer most ring or rings may be outer apertures 320b instead of inner apertures 320a. The number of rings including apertures characterized by a profile similar to 320b may, for any size chamber or wafer, be located at all radial positions beyond 80% of the substrate radius, and may be located at all radial positions beyond 85% of the substrate radius, beyond 90% of the substrate radius, beyond 91% of the substrate radius, beyond 92% of the substrate radius, beyond 93% of the substrate radius, beyond 94% of the substrate radius, beyond 95% of the substrate radius, or further, depending on the sought deposition characteristics at edge regions of the substrate. In some embodiments, apertures having structures similar to outer apertures 320b may be disposed at inner and/or medial positions on the faceplate 300. For example, apertures having a conical aperture profile may be disposed in one or more annular (or other shape) bands at various radial distances of the faceplate 300. In some embodiments, the bands of conical apertures may be disposed within an annular area defined by an inner radial distance from the center of the faceplate 300 and an outer radial distance. Such arrangements may enable film thickness and non-uniformity to be tuned, such as in applications in which a film profile change may be desired.

The use of the larger outer apertures 320b having conical third sections 300 at or near a periphery of the substrate helps create greater deposition at edges of the substrates to achieve greater deposition uniformity across a substrate being processed. Due to their respective geometries, each of the outer apertures 320b may have a greater conductance than each of the inner apertures 320a. For example, each outer aperture 320b may have a conductance of at least 1.5×, at least 1.75×, at least 2.0×, at least 2.25×, etc. the conductance of each inner aperture 320a. Based on the relative conductance between each of the outer apertures 320a and inner apertures 320b, the aperture density (number of apertures per unit area) within a region of inner apertures 320a and a region of outer apertures 320b may be selected to maintain a relatively uniform conductance across the faceplate 300. For example, for outer apertures 320b that have a conductance of approximately twice that of inner apertures 320a, the aperture density in the region of inner apertures 320a may be approximately twice the aperture density of the region of outer apertures 320b.

FIG. 4B shows a schematic bottom plan view of an exemplary faceplate according to some embodiments of the present technology, and may illustrate a schematic view of faceplate 300, for example. As illustrated, faceplate 300 may be divided into a number of zones, with each zone defining a number of apertures. For example, as illustrated faceplate 300 is divided into two zones. A first zone 340 may be generally circular in shape and is centered on the faceplate 300. A number of apertures, such as inner aperture 320a, may be arranged within the first zone 340. For example, the apertures within the first zone 340 may be arranged in a number of concentric rings from a center of the faceplate 300 towards an outer periphery of the first zone 340, although other patterns or arrangements of apertures within the first zone 340 are possible. A second zone 345 may be generally annular in shape. The second zone 345 may extend about and be concentric with the first zone 340. For example, the second zone 345 may extend from the outer periphery of the first zone 340 to the outer periphery of the faceplate 300. A number of apertures, such as outer aperture 320b, may be arranged within the second zone 345. For example, the apertures within the second zone 345 may be arranged in a number of concentric rings from an inner edge of the second zone 345 towards an outer periphery of the second zone 345, although other patterns or arrangements of apertures within the second zone 345 are possible. Second zone 345 may be located at any radial outward dimension as previously described, or may begin at any percentage of the faceplate radius as previously noted. As discussed above, based on the arrangement and geometry of the apertures within each of the first zone 340 and the second zone 345, a conductance of the faceplate 300 may be substantially uniform across both zones 340, 345. For example, each aperture of the second zone 345 may have a conductance that is approximately twice the conductance of each aperture within the first zone 340. To keep the conductance substantially uniform, an aperture density within the first zone 340 may be approximately twice that of the second zone 345. By utilizing larger, conical apertures within the second zone 345, increased ion flow can be provided near peripheral edges of a substrate, resulting in more uniform deposition of gases along the peripheral edges of the substrate.

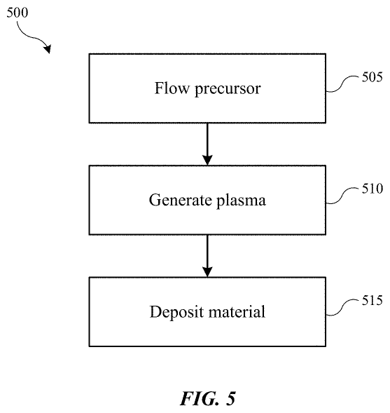

FIG. 5 shows operations of an exemplary method 500 of semiconductor processing according to some embodiments of the present technology. The method may be performed in a variety of processing chambers, including processing system 200 described above, which may include faceplates according to embodiments of the present technology, such as faceplate 300. Method 500 may include a number of optional operations, which may or may not be specifically associated with some embodiments of methods according to the present technology.

Method 500 may include a processing method that may include operations for forming a hardmask film or other deposition operations. The method may include optional operations prior to initiation of method 500, or the method may include additional operations. For example, method 500 may include operations performed in different orders than illustrated. In some embodiments, method 500 may include flowing one or more precursors into a processing chamber at operation 505. For example, the precursor may be flowed into a chamber, such as included in system 200, and may flow the precursor through one or more of a gasbox, a blocker plate, or a faceplate, prior to delivering the precursor into a processing region of the chamber.

In some embodiments, the faceplate may have two concentric zones, with each zone defining a number of apertures. An inner plurality of apertures, similar to inner apertures 320a, may be arranged within an inner circular zone, while an outer plurality of apertures, similar to outer aperture 320b, may be arranged within an outer annular zone. Any of the other characteristics of faceplates described previously may also be included, including any aspect of faceplate 300, such as that the apertures within the annular outer zone may be characterized by a conical or countersunk profile. At operation 510, a plasma may be generated of the precursors within the processing region, such as by providing RF power to the faceplate to generate a plasma. Material formed in the plasma may be deposited on the substrate at operation 515. In some embodiments, depending on the thickness of the material deposited, the deposited material may be characterized by a thickness at the edge of the substrate that is approximately the same as a thickness within a central region of the substrate. For example, the material deposited may be characterized by a thickness proximate an edge of the substrate that is within 500 Å of a material thickness proximate a center of the substrate, and may be characterized by a difference in thickness of less than or about 400 Å from a center, less than or about 300 Å, less than or about 200 Å, less than or about 100 Å, less than or about 50 Å, or less.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing chamber, comprising:
a gasbox;
a substrate support;
a blocker plate positioned between the gasbox and the substrate support, wherein the blocker plate defines a plurality of apertures through the blocker plate; and
a faceplate positioned between the blocker plate and the substrate support, wherein:
the faceplate is characterized by a first surface facing the blocker plate and a second surface opposite the first surface;
the second surface of the faceplate and the substrate support at least partially define a processing region within the semiconductor processing chamber;
the faceplate defines an inner plurality of apertures through the faceplate;
each of the inner plurality of apertures comprises a generally cylindrical aperture profile;
the faceplate defines an outer plurality of apertures through the faceplate that are positioned radially outward from the inner plurality of apertures; and
each of the outer plurality of apertures comprises a conical aperture profile that extends through the second surface of the faceplate.

2. The semiconductor processing chamber of claim 1, wherein:
each of the outer plurality of apertures has a diameter at the second surface of the faceplate that is larger than a corresponding diameter of each of the inner plurality of apertures.

3. The semiconductor processing chamber of claim 1, wherein:
a conductance of the faceplate is substantially constant across all regions of the faceplate.

4. The semiconductor processing chamber of claim 1, wherein:
each of the outer plurality of apertures further comprises an upper aperture profile that extends through the first surface of the faceplate; and
the upper aperture profile is characterized by a substantially cylindrical profile.

5. The semiconductor processing chamber of claim 4, wherein:
each of the outer plurality of apertures further comprises a choke that extends between the upper aperture profile and the conical aperture profile, the choke having a smaller diameter than each of the upper aperture profile and the conical aperture profile.

6. The semiconductor processing chamber of claim 1, wherein:
a portion of each of the inner plurality of apertures and a portion of each of the outer plurality of apertures are characterized by a same diameter.

7. The semiconductor processing chamber of claim 6, wherein:
the portion of each of the inner plurality of apertures extends through the second surface of the faceplate; and
the portion of each of the outer plurality of apertures is disposed at a medial portion of a thickness of the faceplate and is disposed above the conical aperture profile.

8. The semiconductor processing chamber of claim 1, wherein:
the outer plurality of apertures are arranged about the faceplate in a number of circumferentially arranged rows.

9. A semiconductor processing chamber faceplate, comprising:
a first surface and a second surface opposite the first surface, wherein:
the faceplate defines an inner plurality of apertures through the faceplate;
each of the inner plurality of apertures comprises an aperture profile having a generally cylindrical section that extends through the second surface of the faceplate;
the faceplate defines an outer plurality of apertures through the faceplate that are positioned radially outward from the inner plurality of apertures; and
each of the outer plurality of apertures comprises a conical aperture profile that extends through the second surface of the faceplate.

10. The semiconductor processing chamber faceplate of claim 9, wherein:
the inner plurality of apertures are disposed in a central region of the faceplate; and
the outer plurality of apertures are disposed in an annular region of the faceplate that is radially outward from the central region of the faceplate.

11. The semiconductor processing chamber faceplate of claim 10, wherein:
an inner edge of the annular region is positioned at least 135 mm from a center of the faceplate.

12. The semiconductor processing chamber faceplate of claim 9, wherein:
the conical profile of each of the outer plurality of apertures transitions to a choke at a medial position of the faceplate between the first surface of the faceplate and the second surface of the faceplate.

13. The semiconductor processing chamber faceplate of claim 12, wherein:
the aperture profile of each of the outer plurality of apertures transitions from the choke to a substantially cylindrical profile extending to the first surface of the faceplate.

14. The semiconductor processing chamber faceplate of claim 12, wherein:
the generally cylindrical section of the aperture profile of each of the inner plurality of apertures and the choke of each of the outer plurality of apertures have a substantially similar diameter.

15. The semiconductor processing chamber faceplate of claim 14, wherein:
the generally cylindrical section of the aperture profile of each of the inner plurality of apertures has a length that is greater than a length of the choke of each of the outer plurality of apertures.

16. The semiconductor processing chamber faceplate of claim 9, wherein:
the aperture profile of each of the inner plurality of apertures comprises an additional cylindrical section that extends through the first surface of the faceplate; and
the additional cylindrical section has a greater diameter than the generally cylindrical section.

17. The semiconductor processing chamber faceplate of claim 9, wherein:
an aperture density of the inner plurality of apertures is greater than an aperture density of the outer plurality of apertures.

18. The semiconductor processing chamber faceplate of claim 17, wherein:
the aperture density of the inner plurality of apertures is at least twice as great as the aperture density of the outer plurality of apertures.

19. A method of semiconductor processing, comprising:
flowing a precursor into a processing chamber, wherein:
the processing chamber comprises a faceplate and a substrate support on which a substrate is disposed;
a processing region of the processing chamber is at least partially defined between the faceplate and the substrate support;
the faceplate defines an inner plurality of apertures through which the precursor flows;
each of the inner plurality of apertures comprises a generally cylindrical aperture profile;
the faceplate defines an outer plurality of apertures through the faceplate that are positioned radially outward from the inner plurality of apertures; and
each of the outer plurality of apertures comprises a conical aperture profile that extends through a surface of the faceplate facing the substrate support;
generating a plasma of the precursor within the processing region of the processing chamber; and
depositing a material on the substrate.

20. The method of semiconductor processing of claim 19, wherein:
the material deposited is characterized by a thickness proximate an edge of the substrate that is within 500 Å of a thickness proximate a center of the substrate.
